(19) United States
(12) Patent Application Publication
(10) Pub. No.: US 2012/0161312 A1
(43) Pub. Date: Jun. 28, 2012

(54) NON-SOLDER METAL BUMPS TO REDUCE PACKAGE HEIGHT

(76) Inventors: Md Altaf HOSSAIN, Portland, OR (US); Scott A. GILBERT, Chandler, AZ (US)

(21) Appl. No.: 12/978,389

(22) Filed: Dec. 23, 2010

(51) Int. Cl. H01L 23/498; H01L 21/60

(52) U.S. Cl. 257/737; 438/125; 257/E23.06; 257/E21.509

(57) ABSTRACT

Electronic assemblies and their manufacture are described. One assembly includes a substrate and a die on a first side of the substrate. A plurality of non-solder metal bumps are positioned on a second side of the substrate. The assembly also includes a board to which the non-solder metal bumps are coupled. The assembly also includes solder positioned between the board and the substrate, wherein the board is electrically coupled to the substrate through the solder and the bumps. Other embodiments are described and claimed.

### RELATED ART

Integrated circuits may be formed on semiconductor wafers made of materials such as silicon. The semiconductor wafers are processed to form various electronic devices. The wafers are diced into semiconductor chips (a chip is also known as a die), which may then be attached to a package substrate using a variety of known methods. The package substrate may then be attached to a printed circuit board (PCB) such as a motherboard. One type of package substrate is a ball grid array (BGA), which includes a plurality of solder balls on the land side of the package. The die side of the package substrate may be electrically coupled to the land side using internal routing through the substrate. The BGA package including the solder balls on the land side is positioned on a PCB, then heated to reflow the solder balls and form a joint to couple the package to the PCB.

### BRIEF DESCRIPTION OF THE DRAWINGS

Embodiments are described by way of example, with reference to the accompanying drawings, which are not drawn to scale, wherein:

FIG. 1 illustrates a view of assembly components including a die on a substrate, the substrate including non-solder metal bumps, and a board to which the substrate will be attached, in accordance with certain embodiments;

FIG. 2 illustrates a view of the assembly components of FIG. 1, in which the non-solder metal bumps and solder paste on the board are brought into contact, in accordance with certain embodiments;

FIG. 3 illustrates a view of the assembly components of FIGS. 1-2, in which the substrate is coupled to the board through the non-solder metal bumps and solder, in accordance with certain embodiments;

FIG. 4 illustrates a view of an assembly including a package coupled to a board, the package including non-solder metal bumps having a rectangular shape when viewed in cross-section, in accordance with certain embodiments;

FIG. 5 illustrates a view of an assembly including a package coupled to a board, the package including non-solder metal bumps having a curved surface when viewed in cross-section, in accordance with certain embodiments;

FIG. 6 illustrates a flow chart of process operations, in accordance with certain embodiments;

FIG. 7 illustrates an electronic system arrangement in which embodiments may find application.

### DETAILED DESCRIPTION

As electronic devices continue to decrease in size, reduction of the height of the electronic assembly becomes essential. Conventional BGA packages utilize solder balls on the land surface of the package to attach the package to a board. Certain embodiments relate to assemblies and the formation of assemblies in which non-solder metal bumps are used to couple a package to a board, and solder balls are not used. It is expected that the height of the assembly can be substantially decreased by utilizing the non-solder metal bumps.

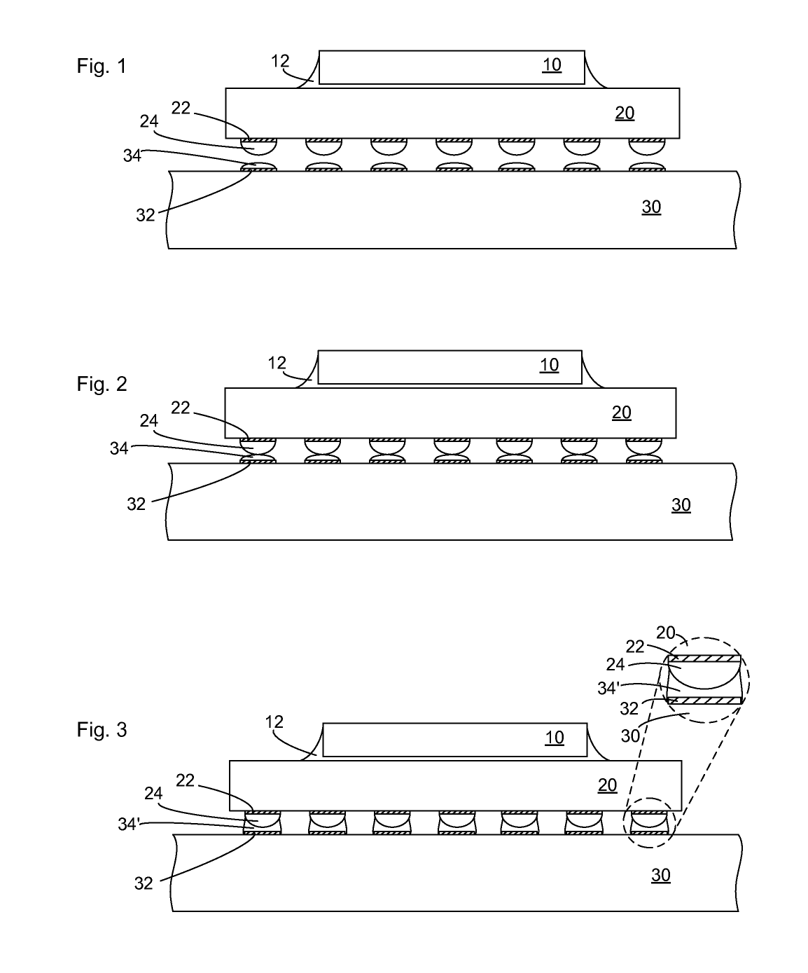

FIGS. 1-3 illustrate operations for forming an assembly in accordance with certain embodiments. As seen in FIG. 1, a die 10 such as a semiconductor chip is coupled to a die side of the package substrate 20 using any suitable attachment method. As illustrated in FIGS. 1-3, the die side is the upper side of the substrate 20. One attachment method is wire bonding. Another attachment method uses a solder bump array in a flip chip configuration, using a method known as a C4 (controlled collapse chip connection) process, in which solder bumps are located between the die and package substrate. In a C4 process, solder paste may be placed on pads on the active side of the die, on the substrate, or on both the die and substrate, using, for example, stencil mask printing. The solder is then melted and permitted to flow, to ensure that each bump fully wets the pad it was formed on. The substrate and die are brought together, and a second reflow operation is carried out, and a solder connection is made between the die pads and the substrate pads. An underfill material 12 may be positioned between the die 10 and the substrate 20, and extend a distance up the sides of the die 10 and on the substrate 20 outside of the die attach area.

The substrate 20 includes a plurality of pads 22 on a land side opposite the die side. As illustrated in FIGS. 1-3, the land side is the lower side of the substrate 20. The pads 20 may be formed from any suitable material including, but not limited to, copper. Positioned on the pads 20 are non-solder metal bumps 24. The non-solder metal bumps are formed from a material having a higher melting point than a solder. Solders have relatively low melting points in the range of 90° C. to 450° C. The non-solder metal bumps may be formed from a suitable metal, including, but not limited to, copper. As used herein, the term metal includes pure metals and alloys.

In certain embodiments, the non-solder metal bumps may be formed on pre-existing bonding pads using any suitable process, for example, a wet plating process that plates the bumps directly onto the metal of the bonding pads. The bumps may then be processed to form a specific shape using any suitable method, for example, etching. If desired, a suitable protective layer (for example, a gold layer or OSP (organic solderability preservative) layer) may be provided on the bump for protection from oxidation and other damage. Depending on the material used, the protective layer may remain on the surface or may be removed during assembly processing.

FIG. 1 also illustrated board 30, which may be a printed circuit board such as a motherboard, to which the substrate 20 will be coupled. The board 30 may include pads 32 for making electrical connections to the substrate 20. Solder paste 34 may be positioned on the pads 32. The solder paste may be selected to be lead free. Lead free solders typically include alloys of tin, silver, and copper (SAC).

As illustrated in FIG. 2, the bumps 24 and solder paste 34 are brought into contact. Then, heat is applied to melt the solder in the solder paste 34. The molten solder 34′ wets the bumps 24. Upon solidification of the solder, a joint is formed between the substrate 20 and the board 30, through the solder and bumps 24, as illustrated in FIG. 3.

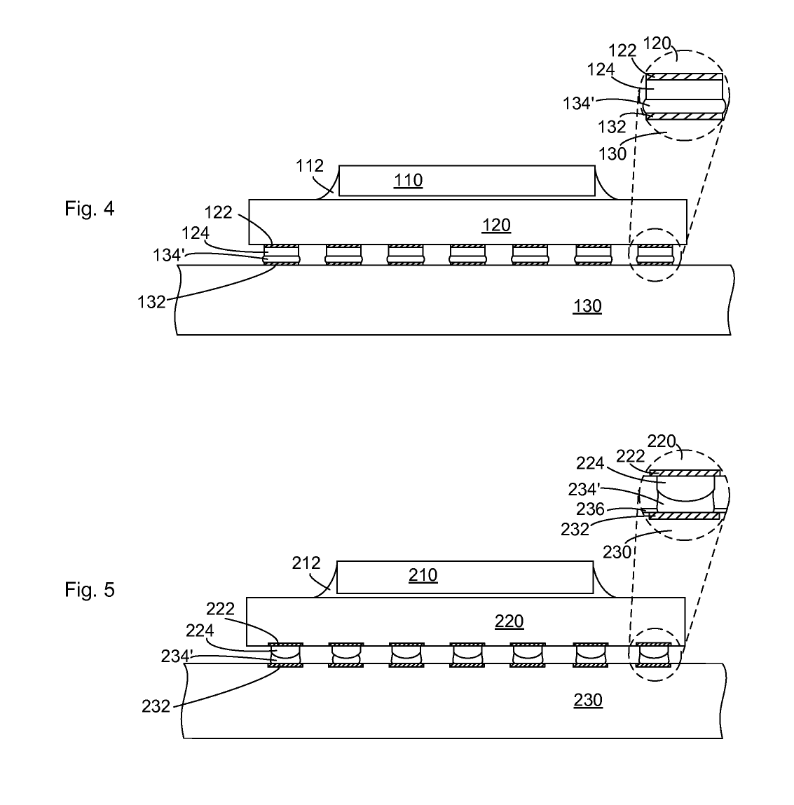

The bumps 24 may be formed using a suitable plating process. In certain embodiments, both the bonding pads 22 and the bumps 24 may be formed from copper. As illustrated in FIGS. 1-3, the bumps 24 may be formed to have a curved surface. A variety of bump shapes are possible. In the embodiment illustrated in FIGS. 1-3, the bumps 24 have a rounded or convex surface. Such a surface shape may ensure good contact even if there is some amount of warpage. It should be appreciated that after the solder 34′ has been melted and a joint formed, the interface between the solder 34′ and the metal bumps 24 may not appear as precise as illustrated in FIG. 3. For example, depending on the materials used, an intermetallic compound may be formed at the interface and the transition from solder to metal may be less smooth than that illustrated in FIG. 3. Similarly, the transition between solder and metal bump in FIGS. 4-5 may also not be as smooth as illustrated in the figures.

FIG. 4 illustrates an assembly including a die 110 coupled to a substrate 120 that is coupled to a board 130. An underfill 112 may be present between the die 110 and substrate 120. Non-solder metal bumps 124 are formed on pads 122 of the substrate 120. The bumps 124 are coupled to solder 134′ on bonding pads 132 on the board 130. In this embodiment, the bumps 124 are formed to have a flat surface that contacts the solder 134.

FIG. 5 illustrates an assembly including a die 210 coupled to a substrate 220 that is coupled to a board 230. An underfill 212 may be present between the die 210 and substrate 220. Non-solder metal bumps 224 are formed on pads 222 of the substrate 220. The bumps 224 are coupled to solder 234′ on bonding pads 232 on the board 230. In this embodiment, the bumps 124 are formed to have flat side surfaces and a curved surface that contacts the solder 134. This embodiment also illustrates the pads 222 being flush with the lower surface of the substrate 200, and pads 232 being flush with the upper surface of the board 230, as illustrated in FIG. 5. If desired, a mask may be used during processing operations to more precisely control the position of the solder. The blown up portion of FIG. 5 (in dotted lines) illustrates the presence of such a mask 236, which in this embodiment extends slightly onto the pads 232 to limit the width of the solder 234′.

It should be appreciated that the design and positioning of the pads in relation to the surfaces of the package substrate and the board (e.g., extending outward, flush with, or recessed) may vary depending on the specific design of the substrate and board, and may take forms different from those illustrated. In addition, in certain embodiments, instead of providing bonding pads and then forming non-solder metal bumps thereon, a single operation may be used to form the non-solder metal bumps without first forming pads.

In addition, as illustrated in certain of the Figures, the non-solder metal bumps are illustrated as having shapes including a curved (convex) surface, a flat surface, and flat sides with a curved lower surface. These configurations may be seen, for example, within the blown up regions of FIGS. 3, 4, and 5 (in dotted lines). A variety of shapes are possible, in addition to those illustrated. The three dimensional shape of the bumps may also be varied, for example, including, but not limited to, cube-like and cylinder-like structures. The three dimensional shapes may include various combinations of curved and flat surfaces.

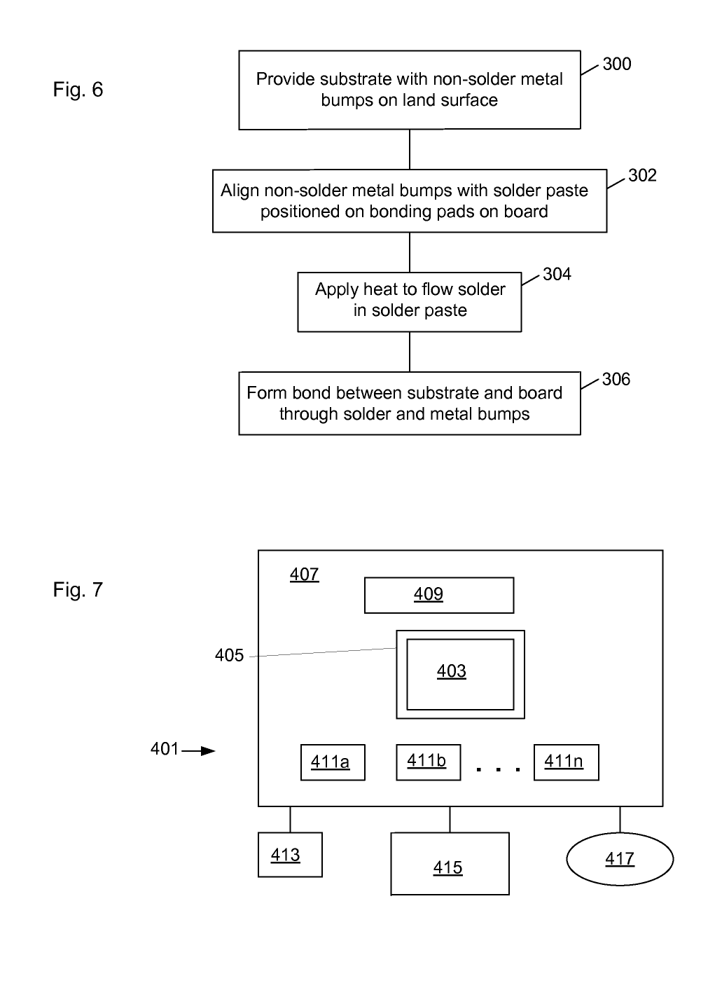

FIG. 6 illustrates a flowchart of operations, in accordance with certain embodiments. Box 300 is providing a substrate with non-solder metal bumps on a land surface thereof. The substrate may include one or more die structures positioned thereon, coupled to the package substrate using any suitable method. The bumps may be positioned on pads on the land surface of the substrate. Box 302 is aligning the non-solder metal bumps on the substrate with solder paste positioned on bonding pads on a board such as a PCB motherboard. Box 304 is applying heat to melt the solder in the solder paste. Box 306 is forming a bond between the substrate and the board through the non-solder metal bumps and the solder.

Certain embodiments may provide one or more of the following advantages when compared with conventional BGA package assemblies and manufacturing processes. First, in accordance with certain embodiments, fewer processing operations may be needed when utilizing non-solder metal bumps than when utilizing conventional solder balls. For example, a conventional BGA processing operation may include the following operations: (i) screen printing solder paste onto pads on the land side of a package substrate; (ii) placing solder balls onto the paste on the pads; (iii) heating and reflowing the solder to attach the solder balls to the pads on the package substrate; (iv) screen printing solder paste onto pads on the board; (v) bringing the solder balls on the package substrate into contact with the solder paste on the board pads; (vi) heating the solder to reflow and form a bond between the package substrate and the board. When utilizing the non-solder metal bumps in accordance with certain embodiments, fewer operations are needed. For example, the bumps may in certain embodiments be formed using a plating process to plate the bumps onto the pads on the package substrate. By forming the bumps on the package substrate pads, the operations (i), (ii), and (iii) above, including screen printing, picking and placing solder balls, and heating the solder, are not necessary.

Second, the height of the non-solder metal bumps may be substantially less than that of a solder ball. In certain embodiments, it is expected that the bump height will be about one half or less than that of conventional solder balls. For example, typical BGA solder ball heights are in the range of 400-600 microns, whereas in certain embodiments non-solder metal bump height may be in the range of 150-300 microns. Other heights are also possible. For small pitch devices (including, but not limited to, assemblies used in cell phones), certain embodiments may include bump sizes in the range of 100 to 200 microns.

Third, a problem with the use of solder balls in conventional BGA assemblies is the collapse of the solder during subsequent heating operations. As a result of this problem, separate stand-off structures may be formed on the surface of the board or package substrate in order to ensure that a minimum distance between the package substrate and board is maintained. The non-solder metal bumps, which melt at a higher temperature than solder balls, can provide the same effect as a separate stand-off structure in maintaining a minimum distance between the package substrate and the board during subsequent heating operations.

Assemblies including components formed as described in embodiments above may find application in a variety of electronic components. FIG. 7 schematically illustrates one example of an electronic system environment in which aspects of described embodiments may be embodied. Other embodiments need not include all of the features specified in FIG. 4, and may include alternative features not specified in FIG. 7.

The system 401 of FIG. 4 may include at least one central processing unit (CPU) 403. The CPU 403, also referred to as a microprocessor, may be a die which is attached to an integrated circuit package substrate 405, which is then coupled to a printed circuit board 407, which in this embodiment, may be a motherboard. The CPU 403 and package substrate 405 coupled to the board 407 is an example of an assembly that may be formed in accordance with embodiments such as described above. A variety of other system components, including, but not limited to memory and other components discussed below, may also include structures formed in accordance with the embodiments described above.

The system 401 may further include memory 409 and one or more controllers 411a, 411b . . . 411n, which are also disposed on the motherboard 407. The motherboard 407 may be a single layer or multi-layered board which has a plurality of conductive lines that provide communication between the circuits in the package 405 and other components mounted to the board 407. Alternatively, one or more of the CPU 403, memory 409 and controllers 411a, 411b . . . 411n may be disposed on other cards such as daughter cards or expansion cards. The CPU 403, memory 409 and controllers 411a, 411b . . . 411n may each be seated in individual sockets or may be connected directly to a printed circuit board or all integrated in the same package. A display 415 may also be included.

Any suitable operating system and various applications execute on the CPU 403 and reside in the memory 409. The content residing in memory 409 may be cached in accordance with known caching techniques. Programs and data in memory 409 may be swapped into storage 413 as part of memory management operations. The system 401 may comprise any suitable computing device, including, but not limited to, a mainframe, server, personal computer, workstation, laptop, handheld computer, netbook, tablet, book reader, handheld gaming device, handheld entertainment device (for example, MP3 (moving picture experts group layer-3 audio) player), PDA (personal digital assistant) telephony device (wireless or wired), network appliance, virtualization device, storage controller, network controller, router, etc.

The controllers 411a, 411b . . . 411n may include one or more of a system controller, peripheral controller, memory controller, hub controller, I/O (input/output) bus controller, video controller, network controller, storage controller, communications controller, etc. For example, a storage controller can control the reading of data from and the writing of data to the storage 413 in accordance with a storage protocol layer. The storage protocol of the layer may be any of a number of known storage protocols. Data being written to or read from the storage 413 may be cached in accordance with known caching techniques. A network controller can include one or more protocol layers to send and receive network packets to and from remote devices over a network 417. The network 417 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

Terms such as “first”, “second”, and the like as used herein to not necessarily denote any particular order, quantity, or importance, but are used to distinguish one element from another. Terms such as “upper” and “lower” and the like as used herein refer to the orientation of features as illustrated in the attached figures.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. An assembly comprising:
a substrate having a die side and a land side opposite the die side;
a die coupled to the die side of the substrate; and
a plurality of non-solder metal bumps on the land side of the substrate.

2. The assembly of claim 1, further comprising a plurality of bonding pads on the land side of the substrate, the non-solder metal bumps being positioned on the bonding pads, the bonding pads positioned between the substrate and the bumps.

3. The assembly of claim 1, further comprising a board, wherein the substrate is coupled to the board, and wherein the bumps comprising copper are positioned between the substrate and the board.

4. The assembly of claim 1, wherein the bumps comprise copper.

5. The assembly of claim 3, further comprising solder between the bump and the board.

6. The assembly of claim 1, wherein the bumps have a curved surface.

7. The assembly of claim 6, wherein the curved surface is convex, and wherein at least a portion of the convex curved surface faces the board.

8. The assembly of claim 5, further comprising a plurality of bonding pads on the board, the solder being positioned between the bump and the bonding pads on the board.

9. An assembly comprising:
a substrate;
a die on a first side of the substrate;
a plurality of non-solder metal bumps on a second side of the substrate a board to which the non-solder metal bumps are coupled; and
solder positioned between the board and the substrate;
wherein the board is electrically coupled to the substrate through the solder and the bumps.

10. The assembly of claim 9, wherein the bumps include a curved surface.

11. The assembly of claim 10, wherein the curved surface is convex, and wherein at least a portion of the convex curved surface faces the board.

12. The assembly of claim 10, further comprising a plurality of bonding pads on the board, the solder positioned between the bump and the bonding pads on the board.

13. The assembly of claim 10, further comprising a plurality of bonding pads on the second side of the substrate, the bumps being positioned on the bonding pads.

14. A method for forming an assembly, comprising:
providing a substrate having a first side and a second side, and a plurality of non-solder metal bumps on the second side;
providing a board having bonding pads thereon;
positioning solder paste between the bumps and the bonding pads on the board; and
heating the solder so that the solder melts; and
solidifying the solder so that a joint is formed between the substrate and the board through the bumps and solder.

15. The method of claim 14, wherein the bumps include a curved surface, and wherein the positioning the solder between the bumps and the bonding pads on the board comprises positioning the curved surface of the bumps into contact with the solder.

16. The method of claim 14, further comprising positioning a die on the first side of the substrate.

17. The method of claim 14, wherein the substrate includes bonding pads, and wherein the bumps are positioned on the bonding pads.
